(19) United States
(12) Patent Application Publication
(10) Pub. No.: US 2016/0033755 A1
(43) Pub. Date: Feb. 4, 2016

(54) OPTICAL SHUTTER BASED ON SUB-WAVELENGTH GRATINGS ACTUATED BY MICROELECTROMECHANICAL SYSTEMS

(71) Applicant: CALIFORNIA INSTITUTE OF TECHNOLOGY, PASADENA, CA (US)

(72) Inventors: Yu HORIE, Pasadena, CA (US); Amir ARBABI, Pasadena, CA (US); Andrei FARAON, La Canada Flintridge, CA (US)

(21) Appl. No.: 14/814,425

(22) Filed: Jul. 30, 2015

Related U.S. Application Data
(60) Provisional application No. 62/032,334, filed on Aug. 1, 2014.

(51) Int. Cl. G02B 26/02; B81B 7/02

(52) U.S. Cl. CPC G02B 26/02; B81B 7/02; B81B 2201/047

(57) ABSTRACT

Methods and systems for control of electromagnetic waves are disclosed. An optical shutter includes a sub-wavelength grating. Each beam of the grating can be controlled by electrostatic or mechanical forces in order to increase or decrease the gap between each beam. Electrostatic or acoustic control of the grating allows an optical shutter to switch on and off.

### CROSS REFERENCE TO RELATED APPLICATIONS

The present application claims priority to U.S. Provisional Patent Application No. 62/032,334, filed on Aug. 1, 2014, the disclosure of which is incorporated herein by reference in its entirety.

### STATEMENT OF INTEREST

This invention was made with government support under DE-SC0001293/T-107196 awarded by the Department of Energy. The government has certain rights in the invention. The invention described herein was made in the performance of work under a NASA contract, and is subject to the provisions of Public Law 96-517 (35 USC 202) in which the Contractor has elected to retain title.

### TECHNICAL FIELD

The present disclosure relates to optical shutters. More particularly, it relates to optical shutter based on sub-wavelength gratings actuated by microelectromechanical systems.

### BRIEF DESCRIPTION OF DRAWINGS

The accompanying drawings, which are incorporated into and constitute a part of this specification, illustrate one or more embodiments of the present disclosure and, together with the description of example embodiments, serve to explain the principles and implementations of the disclosure.

FIG. 1 illustrates a cross-sectional schematic of one embodiment of the device of the present disclosure.

FIG. 2 illustrates reflection spectrum changes caused by the actuation of the grating.

FIG. 3 illustrates an exemplary electrical control arrangement with each pair of grating bars.

FIG. 4 illustrates suspended beams for a grating.

FIG. 5 illustrates transparent beams on a grating.

FIG. 6 illustrates an exemplary embodiment of electrodes on a grating.

### SUMMARY

In a first aspect of the disclosure, an optical shutter is described, the optical shutter comprising: a sub-wavelength grating comprising a plurality of parallel beams suspended, at each end, on a side structure; and electrodes connected to each beam of the plurality of parallel beams, wherein each beam is electrically connected to an opposite voltage relative to an immediately adjacent beam.

In a second aspect of the disclosure, a method to control transmission of electromagnetic waves is described, the method comprising: providing a shutter comprising: a sub-wavelength grating comprising a plurality of parallel beams suspended, at each end, on a side structure, and electrodes connected to each beam of the plurality of beams, wherein a first beam and every other beam from the first beam is electrically connected to a first voltage, and all remaining beams are electrically connected to a second voltage; and applying the first and second voltage, wherein the first voltage is higher than the second voltage, based on a desired closed or open position of the shutter.

In a third aspect of the disclosure, a method to control transmission of electromagnetic waves is described, the method comprising: providing a shutter comprising: a sub-wavelength grating comprising a plurality of parallel beams suspended, at each end, on a side structure, and means to apply acoustic waves to each beam of the plurality of beams; and applying acoustic waves to each beam of the plurality of beams based on a desired closed or open position of the shutter.

### DETAILED DESCRIPTION

An optical shutter is a device that controls a light beam intensity for a given period of time, and is typically used for gating laser beams, precise exposure time control, or simply blocking unwanted light. Mechanical iris shutters are very common but may not be suitable for fast and precise timing control. More sophisticated shutters are based on ferroelectric liquid crystals sandwiched by two identical polarizers, see Ref [1]. In this type of shutters, the shuttering speed is limited by the rotational speed of the liquid crystal molecules, typically less than a kHz. Recently, the use of phase transition materials such as vanadium dioxide (VO₂), see Ref [2], was proposed to realize an ultrafast optical shutter.

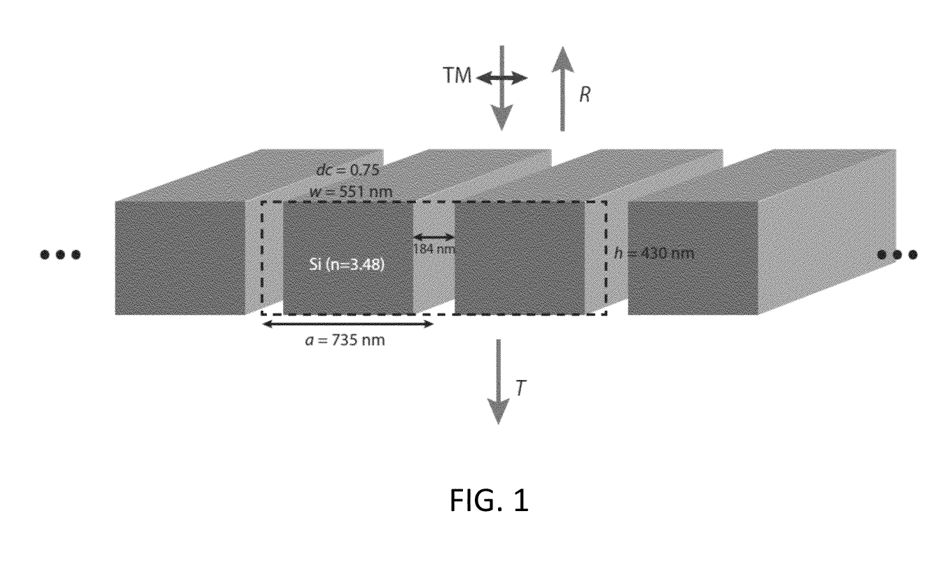

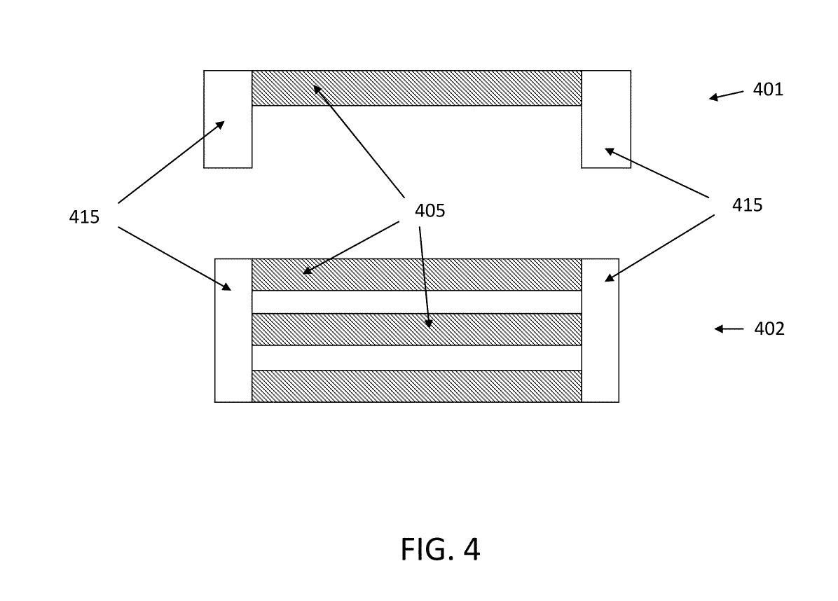

The optical shutters described in the present disclosure utilize sub-wavelength gratings made of high refractive index materials, where the grating bars are dynamically actuated by microelectromechanical systems (MEMS), for example based on electrostatic forces. Owing to the lightweight design for the gratings described in the present disclosure, which can be combined with MEMS technology, faster shuttering speeds can be achieved. These shuttering speeds can then be limited only by the mechanical frequency of the grating bars. The sub-wavelength grating design of the present disclosure is based on a high contrast grating (HCG), see Ref [3], where sub-wavelength gratings made of high refractive index silicon are air-suspended, as shown for example in FIGS. 1 and 4.

In the embodiment of FIG. 1, the grating comprises sections of Si with a height of 430 nm, a width of 551 nm, a gap of 184 nm and a spacing of 735 nm.

High contrast gratings are single layer near-wavelength grating physical structures where the grating material has a large contrast in index of refraction compared to its surroundings. The term near-wavelength refers to the grating period.

High contrast gratings can have many distinct attributes that are not found in conventional gratings. These features include broadband ultra-high reflectivity, broadband ultra-high transmission, and very high quality factor resonance, for optical beam normal or in oblique incidence to the grating surface. High reflectivity gratings can be ultrathin, for example less than 0.15 of the optical wavelength. The reflection and transmission phase of the optical beam through the high contrast grating can be engineered to cover a full 2π range while maintaining a high reflection or transmission coefficient.

The grating bars of a high contrast grating can be considered as a periodic array of waveguides with an electromagnetic wave being guided along the grating thickness direction. Upon plane wave incidence, depending on wavelength and grating dimensions, only a few waveguide-array modes are excited. In standard high contrast gratings, due to the large index contrast and near-wavelength dimensions, there exists a wide wavelength range where only two waveguide-array modes have real propagation constants in the z direction and, hence, carry energy. The two waveguide-array modes depart from the grating input plane, propagate downward to the grating exiting plane, and then reflect back up. After propagating through the grating thickness, each propagating mode can accumulate a different phase. At the exiting plane, owing to a strong mismatch with the exiting plane wave, the waveguide modes not only reflect back to themselves but also couple into each other. As the modes propagate and return to the input plane, similar mode coupling occurs. Following the modes through one round trip, the reflectivity solution can be attained. The two modes can interfere at the input and exiting plane of the high contrast grating, leading to various distinct properties. Some of the properties of standard high contrast gratings can be applied to the gratings of the present disclosure.

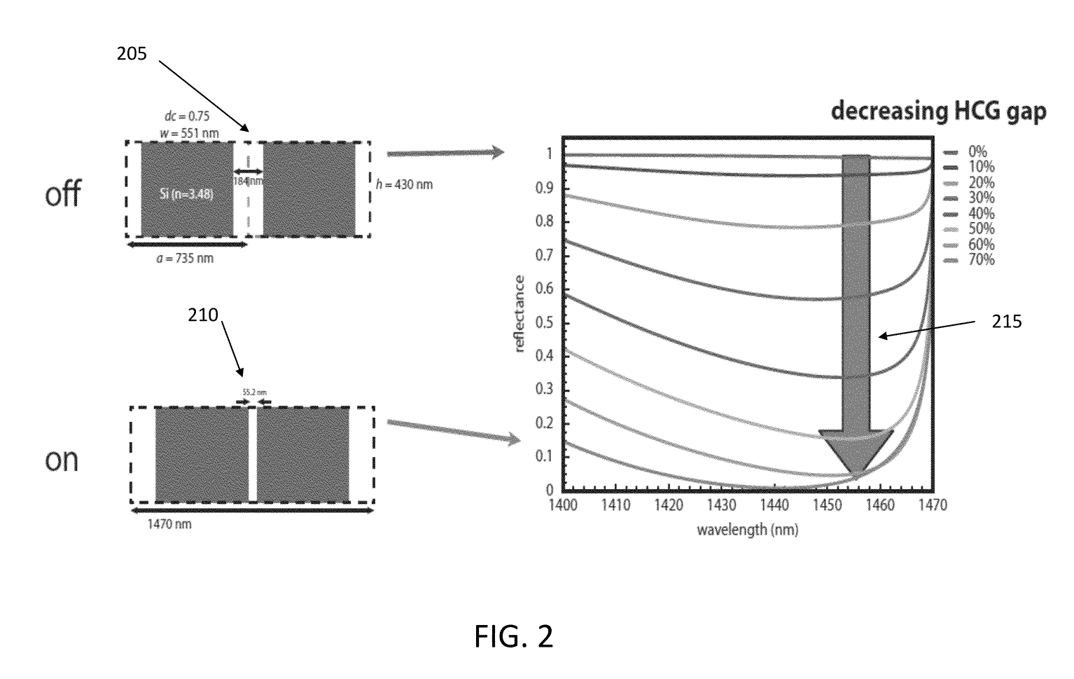

The exemplary sub-wavelength grating design shown in FIG. 1 exhibits a broadband reflection for normally incident TM polarized light around a wavelength λ=1550 nm. When two grating bars move towards each other the gap between the two grating bars becomes narrower, the reflection spectrum dramatically changes and becomes very transmissive, as plotted in FIG. 2.

For example, if the original 184 nm gap size (205) between every two pairs of grating bars is decreased to 55.2 nm (210, a 70% change), the reflectivity for the grating goes down (215) to less than 10% for the wavelength range of 50 nm around λ=1440 nm. Since the gratings are still in the sub-wavelength regime, no higher-order diffraction exists. The sub-wavelength grating bars can be actuated, for example, by electrostatic forces by applying a voltage to the grating bars in pairs, so that attractive/repulsive electrostatic forces act on each pair of grating bars, allowing control of the device. RCWA calculations for the reflectivity spectra are illustrated in FIG. 2.

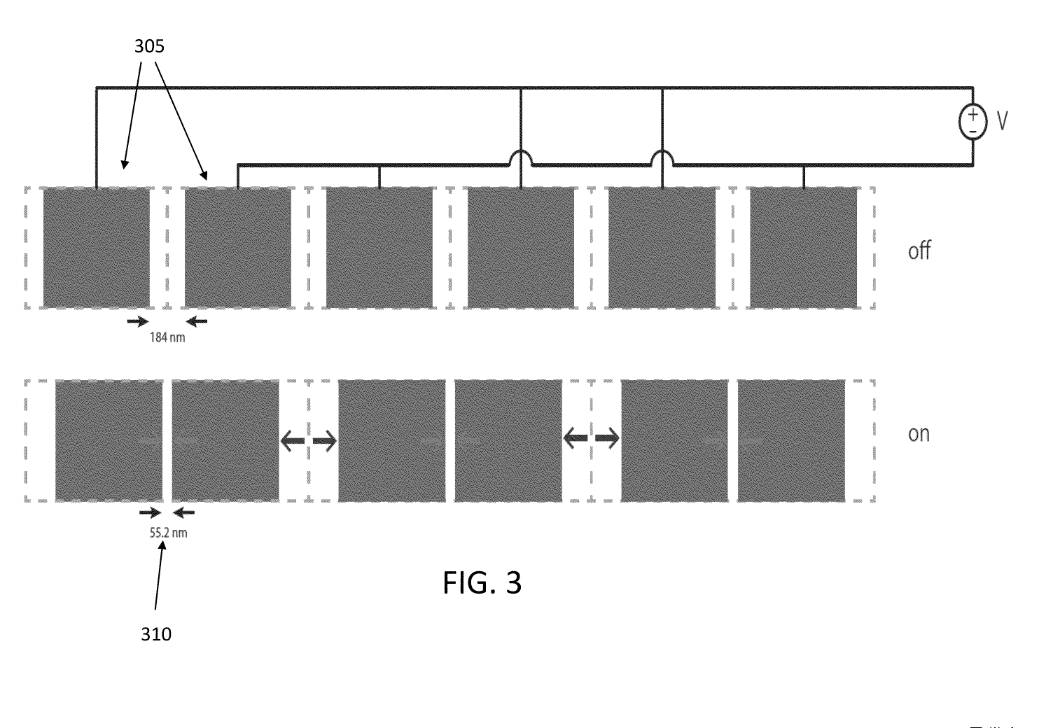

FIG. 3 illustrates an exemplary arrangement where each pair of grating bars, for example pair (305) is connected to a voltage supply. The electrostatic force between each pair causes an attractive force and a decrease in the gap (310). By controlling the gap between the bars, the grating response to the electromagnetic waves can be controlled, thereby allowing operation of the shutter in the closed and open positions.

The bars of the grating can be coupled in pairs to the voltage supply, as illustrated in FIG. 3. In some embodiments, the electrical connections to the bars of the gratings comprise transparent electrodes, for example indium tin oxide (ITO) electrodes. Other materials may be used for the grating, instead of Si, for example SiN.

Regarding the operation speed of optical shutter, the mechanical resonance will impose a limit on the response time of the actuation, which can be expected to be driven at MHz frequencies, see Ref [4].

The beams of the grating can be suspended at each end, in order to allow their free movement relative to each other, as caused by electrostatic forces. For example, as visible in FIG. 4 as side view (401) and top view (402), the beams of the grating (405) may be suspended at each end to a side structure (415), for example a Si structure.

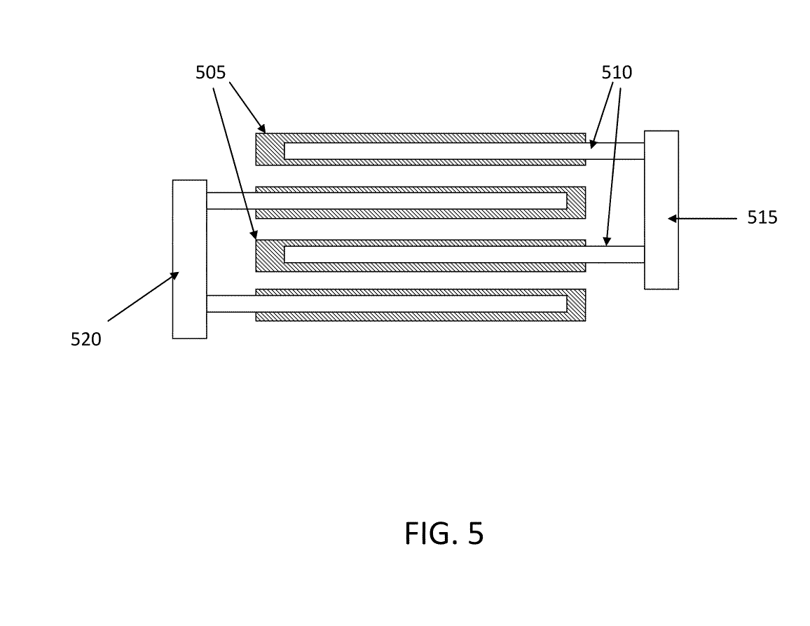

FIG. 5 illustrates an exemplary implementation of the actuation method of FIG. 3. Each pair of beams in the grating is connected to an opposite voltage. For example, bars (505) are connected to one voltage (515) through transparent ITO electrodes (510) covering the majority (or entirety) of the bars, while the remaining bars are connected to the opposite voltage (520).

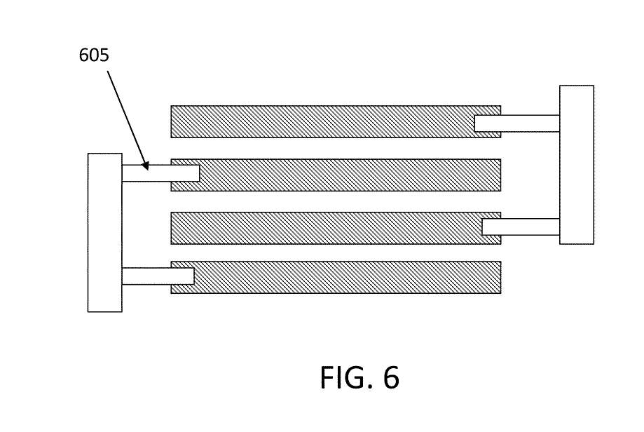

FIG. 6 illustrates an alternative embodiment of FIG. 5, where the electrodes (605) are only connected to a small part of the surface of the bars. For this embodiment, transparent electrodes may be used. In some embodiments, non transparent electrodes may also be used, if the electrodes do not interfere with the operation of the shutter. For example, the grating may extend to a larger area than the area of the beam, therefore the electrodes would be outside the area of the beam while still being able to actuate the shutter in the ON and OFF positions.

In some embodiments, the gap between parallel beams can be between 200 nm and 1 nm.

In some embodiments, the actuation of the beams of the grating is carried out through the application of acoustic waves. In some embodiments, the gratings can be made from materials different than silicon, such as, for example, germanium, gallium arsenide, gallium phosphide, silicon nitride or materials with similar properties.

A number of embodiments of the disclosure have been described. Nevertheless, it will be understood that various modifications may be made without departing from the spirit and scope of the present disclosure. Accordingly, other embodiments are within the scope of the following claims.

The examples set forth above are provided to those of ordinary skill in the art as a complete disclosure and description of how to make and use the embodiments of the disclosure, and are not intended to limit the scope of what the inventor/inventors regard as their disclosure.

Modifications of the above-described modes for carrying out the methods and systems herein disclosed that are obvious to persons of skill in the art are intended to be within the scope of the following claims. All patents and publications mentioned in the specification are indicative of the levels of skill of those skilled in the art to which the disclosure pertains. All references cited in this disclosure are incorporated by reference to the same extent as if each reference had been incorporated by reference in its entirety individually.

It is to be understood that the disclosure is not limited to particular methods or systems, which can, of course, vary. It is also to be understood that the terminology used herein is for the purpose of describing particular embodiments only, and is not intended to be limiting. As used in this specification and the appended claims, the singular forms “a,” “an,” and “the” include plural referents unless the content clearly dictates otherwise. The term “plurality” includes two or more referents unless the content clearly dictates otherwise. Unless defined otherwise, all technical and scientific terms used herein have the same meaning as commonly understood by one of ordinary skill in the art to which the disclosure pertains.

The references in the present application, shown in the reference list below, are incorporated herein by reference in their entirety.

### REFERENCES

[1] “Optical shutter in newports webpage,” http://assets.newport.com/pdfs/e5598.pdf, accessed: Jul. 7, 2014.

[2] M. Rini, A. Cavalleri, R. W. Schoenlein, R. L'opez, L. C. Feldman, J. Richard F Haglund, L. A. Boatner, and T. E. Haynes, “Photoinduced phase transition in VO2 nanocrystals: ultrafast control of surface-plasmon resonance,” Opt. Lett. 30, 558 (2005).

[3] C. J. Chang-Hasnain and W. Yang, “High-contrast gratings for integrated optoelectronics,” Adv. Opt. Photonics 4, 379 (2012).

[4] J. Y. Ou, E. Plum, J. Zhang, and N. I. Zheludev, “An electromechanically reconfigurable plasmonic metamaterial operating in the near-infrared,” Nature Nanotech. 8, 252 (2013).

What is claimed is:

1. An optical shutter comprising:
a sub-wavelength grating comprising a plurality of parallel beams suspended, at each end, on a side structure; and
electrodes connected to each beam of the plurality of parallel beams, wherein each beam is electrically connected to an opposite voltage relative to an immediately adjacent beam.

2. The optical shutter of claim 1, wherein the sub-wavelength grating is made of silicon.

3. The optical shutter of claim 2, wherein the electrodes are made of indium tin oxide.

4. The optical shutter of claim 3, wherein the electrodes cover a majority top surface of the parallel beams.

5. The optical shutter of claim 2, wherein the electrodes cover a minority top surface of the parallel beams.

6. The optical shutter of claim 3, wherein a gap between the parallel beams is between 200 nm and 1 nm.

7. A method to control transmission of electromagnetic waves, the method comprising:
providing a shutter comprising:
a sub-wavelength grating comprising a plurality of parallel beams suspended, at each end, on a side structure, and electrodes connected to each beam of the plurality of beams, wherein a first beam and every other beam from the first beam is electrically connected to a first voltage, and all remaining beams are electrically connected to a second voltage; and
applying the first and second voltage, wherein the first voltage is higher than the second voltage, based on a desired closed or open position of the shutter.

8. The method of claim 7, wherein the sub-wavelength grating is made of silicon.

9. The method of claim 8, wherein the electrodes are made of indium tin oxide.

10. The method of claim 9, wherein the electrodes cover a majority top surface of the parallel beams.

11. The method of claim 8, wherein the electrodes cover a minority top surface of the parallel beams.

12. The optical shutter of claim 9, wherein a gap between the parallel beams is between 200 nm and 1 nm.

13. The method of claim 12, wherein applying the first and second voltage comprises at least:
for a first, second, third and fourth beam being successive beams in the sub-wavelength grating, applying the first voltage to the first and third beam and the second voltage to the second and fourth beam; and
through the applying the first voltage and second voltage, reducing a gap between the first and second beam, and reducing a gap between the third and fourth beam while increasing a gap between the second and third beam.

14. A method to control transmission of electromagnetic waves, the method comprising:
providing a shutter comprising:
a sub-wavelength grating comprising a plurality of parallel beams suspended, at each end, on a side structure, and means to apply acoustic waves to each beam of the plurality of beams; and
applying acoustic waves to each beam of the plurality of beams based on a desired closed or open position of the shutter.

15. The method of claim 14, wherein applying acoustic waves comprises at least:
applying acoustic waves to a first, second and third beam, the first, second and third beam being successive beams in the sub-wavelength grating; and
through the acoustic waves, reducing a gap between the first and second beam while increasing a gap between the second and third beam.

16. The optical shutter of claim 15, wherein a gap between the parallel beams is between 200 nm and 1 nm.

17. The optical shutter of claim 16, wherein the sub-wavelength grating is made of silicon.

18. The method of claim 7, wherein the sub-wavelength grating is made of a material selected from the group comprising: germanium, gallium arsenide, gallium phosphide and silicon nitride.

19. The optical shutter of claim 16, wherein the sub-wavelength grating is made of a material selected from the group comprising: germanium, gallium arsenide, gallium phosphide and silicon nitride.
